(19) United States
(12) Patent Application Publication
(10) Pub. No.: US 2001/0027036 A1
(43) Pub. Date: Oct. 4, 2001

(54) Electrical connector

(76) Inventor: Masayuki Goto, Tokyo (JP)

Correspondence Address: KENESAKA & TAKEUCHI, 1423 Powhatan Street, Alexandria, VA, 22314, US

(21) Appl. No.: 09/812,999

(22) Filed: Mar. 21, 2001

(30) Foreign Application Priority Data
Mar. 28, 2000 (JP) 12-87871

(51) Int. Cl. H05K 1/00

(52) U.S. Cl. 439/74

(57) ABSTRACT

An electrical connector (10) comprises a connector housing (11) having a side wall (13) to define a receiving space (14) for receiving a mating connector (30) mounted on a surface (P2) by means of a connection section (42A) of a contact element (40) that extends outwardly from a housing (31) of the mating connector (30); at least one guiding section (17) provided on a front face of the side wall (13) in an area where no connection section of the mating connector is present and accommodating the connection section (42A) of the mating connector (40) when the mating connector (40) is plugged into the electrical connector (10); and at least one guiding face (18) provided on the guiding section (17).

### BACKGROUND OF THE INVENTION

1. Field of the Invention

The present invention relates to electrical connectors and, more particularly, to an electrical connector for plugging with a mating connector that is surface mounted on a circuit board, etc.

2. Description of the Related Art

Japanese patent application Kokai No. 8-148240 discloses a connector system of this type. As shown in FIG. 5, this connector system comprises a pair of connectors 50 and 60 that are surface mounted on circuit boards 55 and 65, respectively, and plugged with each other. Each contact element 51 for the connector 50 has an L-shaped form and a connection section 51A extending along the attachment face of the housing 52. Each contact element 61 for the connector 60 has a U-shaped connection section 61A along the attachment face of a housing 62. The connection sections 51A and 61A are soldered by surface mount techniques to circuit traces 55A and 65A of the circuit boards 55 and 65, respectively.

In use, the plugging projection 54 of the connector 50 is plugged into the receiving cavity 64 defined by the wall section 63 of a housing 62 of the connector 60, with the wall section 63 being plugged into the receiving space 53 provided in a housing 52 of the connector 50. The edges of the receiving space 53 and the receiving cavity 64 are tapered to form guiding faces 50A and 60A, respectively, facilitating the plug-in operation.

There is a demand for reducing the height of the plugged-in connectors to reducing the distance between the boards, minimizing the equipment size. Even if the connector 60 is plugged completely in the connector 50 as shown by phantom lines, there is a gap (H) between the circuit board 65 and the front face of the connector 50, hindering the miniaturization. These connectors are already very compact, and it is impractical to reduce the size of the guiding faces 50A and 60A for the miniaturization.

### SUMMARY OF THE INVENTION

Accordingly, it is an object of the invention to provide a surface-mount electrical connector having a low plug-in height with a satisfactory guiding face.

An electrical connector related to the invention comprises a connector housing having a side wall to define a receiving space for receiving a mating connector mounted on a surface by means of a connection section of a contact element that extends outwardly from a housing of the mating connector.

According to the invention, at least one guiding section is provided on a front face of the side wall in an area where the connection section of the mating connector is not present and accommodating the connection section of the mating connector when the mating connector is plugged into the electrical connector; and at least one guiding face provided on the guiding section. The guiding section accommodates the leg section of the mating connector so that the front face of the guiding section is brought very close to the surface on which the mating connector is mounted.

According to an embodiment of the invention, the guiding section is provided outside an area where a contact element is provided. It is preferred that the guiding section has a first segment extending in a first direction in which contact elements are arranged and a second segment extending in a second direction perpendicular to the first direction. The guiding sections are provided on opposite sides of the connector housing in the first direction. With such a structure, the guiding section can be made large in a plane perpendicular to the plugging direction by making use of the side wall of the plugging cavity, thus preventing an increase of the connector width.

It is preferred that the front face of the housing is in the same level except for the guiding section so that the vacuum device in an automated assembly line can transport the connector in a stable state. Where the electrical connector is of a surface mount type, the surface does not present any problem with the plugging operation. The guiding face can be provided on the mating connector or both of the connectors. That is, an electrical connector system includes first and second electrical connectors. The first electrical connector comprises a first housing; at least one contact element having a leg section extending outwardly to provide a connection portion that is surface mounted on a first surface. The second electrical connector comprises a second housing having a side wall to define a plugging cavity for receiving the first electrical connector surface mounted on the first surface; at least one guiding section provided on a front edge of the plugging cavity or a peripheral edge of the first housing; and at least one guiding face provided on the guiding section for accommodating the leg section of the first electrical connector in an area that does not correspond to the leg section when the first electrical connector is plugged into the second electrical connector.

### BRIEF DESCRIPTION OF THE DRAWINGS

FIG. 1 is a perspective view of an electrical connector according to an embodiment of the invention;

FIG. 2 is a side view of the connector with a mating connector as viewed in the Y direction of FIG. 1;

FIG. 3 is a sectional view of the connector with the mating connector taken along a YZ plane of FIG. 1;

FIG. 4 is a side view of part of an electrical connector with a mating connector according to another embodiment of the invention; and

FIG. 5 is a sectional view of a conventional electrical connector.

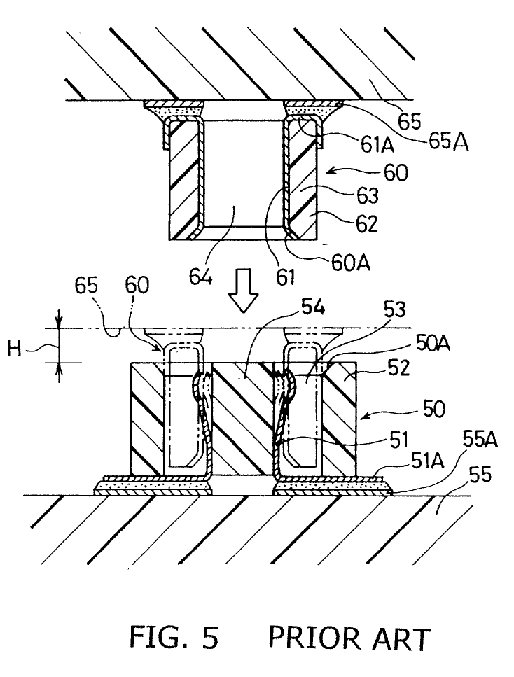

### DESCRIPTION OF THE PREFERRED EMBODIMENTS

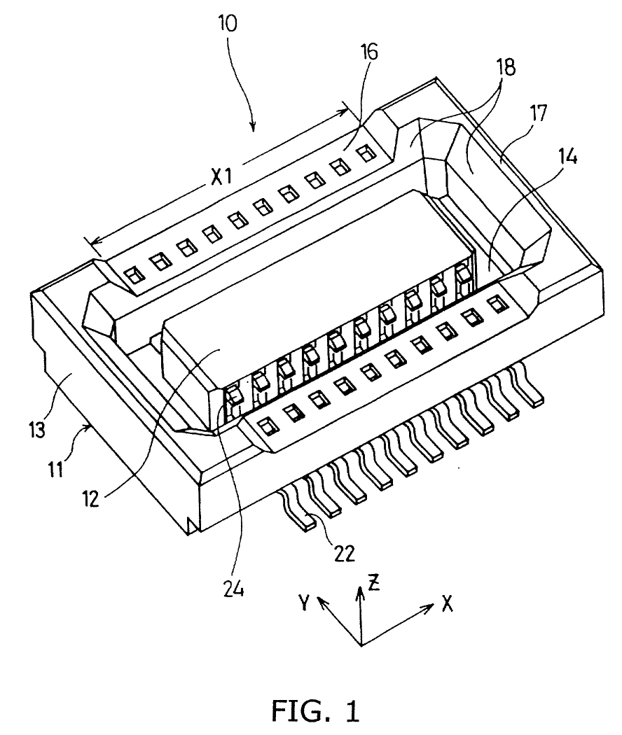

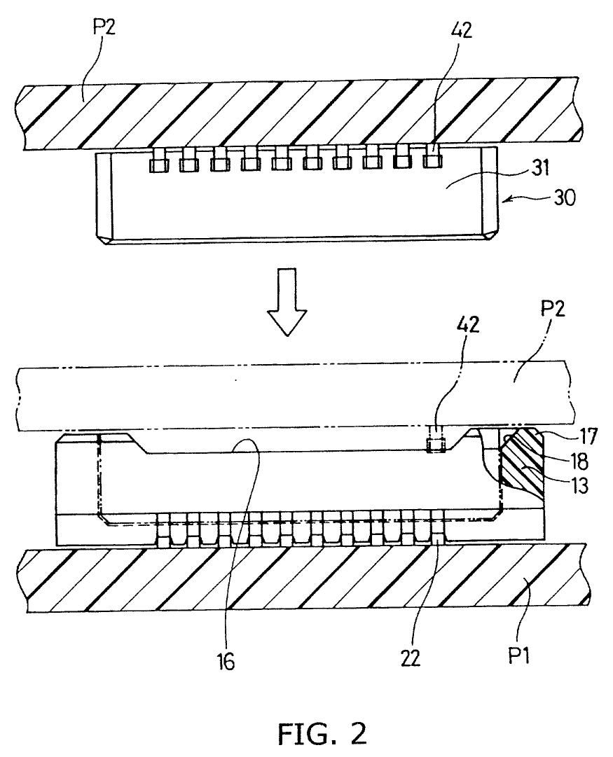

In FIG. 1, a connector 10 comprises a housing 11 having a thin rectangular form extending in the X and Y directions and a protruded land 12 at the center. A receiving space 14 is defined by the protruded land 12 and a surrounding wall 13 so as to open in the Z direction. A mating connector 30 is plugged into the receiving space 14 as shown by phantom lines in FIG. 2.

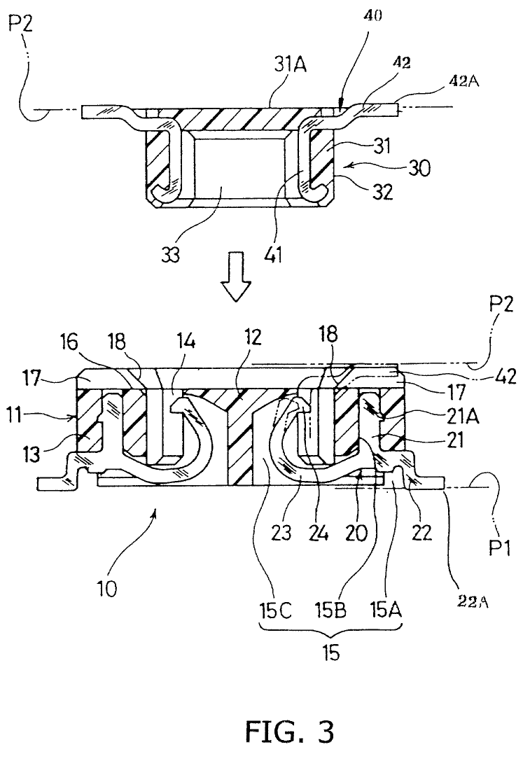

A plurality of contact elements 20 are arranged in the X direction on opposite sides of the housing 11. Each contact element 20 is stamped out of a metal sheet extending in the Y and Z directions. As best shown in FIG. 3, the contact elements 20 are disposed symmetrically and each have a central fixing section 21, a leg section 22 extending outwardly from the fixing section 21 in a Z-shaped form, forming a connection portion 22A at the end, and a resilient arm 23 extending inwardly from the fixing section 21 in a C-shaped form to provide a contact portion 24 at the free end. The fixing section 21 extends upwardly and has an engaging projection 21A. The connection portion 22A is level with or slightly lower than the bottom face of the housing. The connection portion 22A is placed on a circuit board P1 and soldered to a circuit trace of the circuit board P1.

A plurality of receiving slots 15 are provided in the housing 11 to receive the contact elements 20. Each receiving slot 15 opens at the bottom of the housing 11 and an entrance portion 15A for accommodating a linking area where the fixing section 21, the leg section 22, and the resilient arm 23 are linked, a fixing groove 15B into which the fixing section 21 is press fitted, and a slot cavity 15C provided in the protruded land 12 to permit resilient deformation of the resilient arm 23. Each contact element 20 is inserted into one of the receiving slots 15 from below. The engaging projection 21A of the fixing section 21 engages the inner surface of the fixing groove 15B to secure the contact element 20 to the housing 11 such that the contact portion 24 projects into the receiving space 14 of the housing 11.

The front face of the housing 11 has a pair of step-down faces 16 in an arranging area X1 where the contact elements 20 are arranged in the X direction, forming a pair of C-shaped guiding sections 17 on opposite sides of the housing 11. Sloped guiding faces 18 are provided on the front inner edges of the guiding sections 17, extending downwardly more than the step-down faces 16.

The mating connector 30 is mounted on the surface of a board P2 (SMT). The outside form 32 of a housing 31 is made to match the shape of the receiving space 14 of the connector 10. A receiving cavity 33 is provided at the center of the housing 31 to receive the protruded land 12 of the connector 10. A plurality of contact elements 40 are provided on the inside faces of the receiving cavity 33. Each contact element 40 is stamped from a metal sheet to provide a contact section 41 supported on the inside face of the receiving cavity 33 and a leg section 42 extending outwardly from the contact section 41 to the outside of the housing 31 to form a connection portion 42A that is level with or slightly higher than the bottom face 31A of the housing 31. The mating connector 30 is mounted on the circuit board P2 and the connection portions 42A are soldered to the corresponding circuit traces.

In use, when the mating connector 30 is plugged into the connector 10, the guiding sections 17 outside the arranging area X1 accommodate the leg portions 42 of the mating connector 30 as shown by phantom line in FIG. 3. Consequently, the front face of the guiding sections 17 is brought very close to the circuit board P2 of the mating connector 30.

The large guiding faces 18 make it easy to receive the mating connector 30. Where large guiding faces 18 are not required, the height of the connector can be reduced. Plugging the connectors mounted on the circuit boards is very difficult, and the guiding faces are very helpful. The reduction of the connector height makes it possible to reduce the size of the equipment using the connector. The step-down faces 16 of the side walls 13 and the front face of the protruded land 12 lie in the same plane so that when the connector 10 is transported by a vacuum device to the circuit board, the side walls 13 is also supported by the vacuum device to thereby stabilize the posture of the connector 10. The protruded land 12 is not essential for the invention because the surrounding wall defining a receiving cavity is sufficient to receive the mating connector.

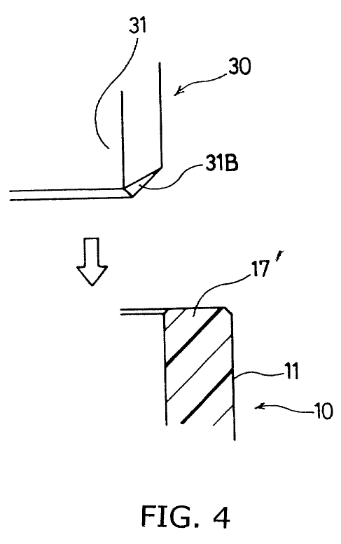

The sloped guiding faces may be provided on the mating connector. The relative position between the guiding faces and the leg portions of the mating connector is the same as that of FIGS. 1-3. FIG. 4 shows a guiding section 17′ of the connector 10 and such a sloped guiding face 31B provided on the housing 31 of a mating connector 30. Such guiding faces as the ones 18 and 31B may be provided on both the connectors 10 and 30, respectively. In the above embodiments, a guiding face may be provided on any segment of the C-shaped guiding section 17. The contact elements may be made by bending as well as stamping.

As has been described above, according to the invention, the guiding faces are provided on the housing to accommodate the leg portions of a surface mounted mating connector so that not only the guiding faces can be made large without increasing the connector height in the plugging direction but also the guided plugging operation is made easy. In other words, if the guiding faces are the same in size as the conventional ones, it is possible to reduce the connector size in the plugging direction. In addition, the front face of the guiding section is brought so close to the circuit board of a mating connector that the stable plugging condition is obtained.

1. An electrical connector comprising:
a connector housing having a side wall to define a receiving space for receiving a mating connector mounted on a surface by means of a connection section of a contact element that extends outwardly from a housing of said mating connector;
at least one guiding section provided on a front face of said side wall in an area where said connection section of said mating connector is not present and accommodating said connection section of said mating connector when said mating connector is plugged into said electrical connector; and
at least one guiding face provided on said guiding section.

2. The electrical connector according to claim 1, wherein said guiding section is provided in an area where no contact element is provided.

3. The electrical connector according to claim 1 or 2, wherein said guiding section has a first segment extending in a first direction in which contact elements are arranged and a second segment extending in a second direction perpendicular to said first direction.

4. The electrical connector according to claim 3, wherein a pair of said guiding sections are provided on opposite sides of said connector housing in said first direction.

5. The electrical connector according to claim 1, wherein said connector housing has a front face that is in the same level except for said guiding section.

6. The electrical connector according to claim 1, wherein said electrical connector is of surface mount type.

7. An electrical connector system including first and second electrical connectors, wherein said first electrical connector comprises:
a first housing;
at least one contact element having a leg section extending outwardly to provide a connection portion that is surface mounted on a first surface; and said second electrical connector comprises:
a second housing having a side wall to define a receiving space for receiving said first electrical connector that is surface mounted on said first surface;
at least one guiding section provided on a front edge of said receiving space or a front edge of said first housing; and
at least one guiding face provided on said guiding section for accommodating said leg section of said first electrical connector when said first electrical connector is plugged into said second electrical connector.
